(19) United States
(12) Patent Application Publication
(10) Pub. No.: US 2012/0235970 A1
(43) Pub. Date: Sep. 20, 2012

(54) THIN FILM DESICCANT AND METHOD OF FABRICATION

(75) Inventors: Kristopher A. Lavery, San Jose, CA (US); Bangalore R. Natarajan, Cupertino, CA (US)

(73) Assignee: QUALCOMM MEMS Technologies, Inc., San Diego, CA (US)

(21) Appl. No.: 13/052,018

(22) Filed: Mar. 18, 2011

(51) Int. Cl. G06F 3/038; H05K 7/04; B23P 19/00; B65D 81/26; H05K 13/00

(52) U.S. Cl. 345/211; 206/204; 29/825; 29/428; 361/807

(57) ABSTRACT

This disclosure provides systems, methods and for providing a desiccant in a MEMS package. A MEMS device may be packaged with a desiccant to provide a moisture-free environment. In order to avoid undesirable effects on the MEMS device, the desiccant may be selected or treated so as to be compatible with a particular MEMS device, for instance, a very thin profile may be desired. A method for covalently bonding zeolite crystals with a substrate is provided such that a layer of zeolite crystals is covalently attached to a substrate surface of the MEMS device package. This bonding includes a change in the chemical structure of the zeolite such that is chemically adhered to the substrate.

### TECHNICAL FIELD

This disclosure relates to systems and methods to bond zeolite particles to a glass or silicon oxide surface to control the moisture level in an electronic device. This disclosure also relates to a process for bonding zeolite particles to a substrate by changing the physical and chemical properties of the zeolite so that the zeolite bonds to the substrate.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a metallic membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

MEMS devices, and in particular MEMS devices such as interferometric modulators, are sensitive to environmental conditions such as humidity. Generally, it is desirable to minimize the permeation of water vapor into a package structure and thus control the environment inside the package described below, and hermetically seal it to ensure that the environment remains constant. When the humidity within the package exceeds a level beyond which surface tension from the moisture becomes higher than the restoration force of a movable element in a MEMS device such as the interferometric modulator array, the movable element may become stuck to an adjacent surface for a prolonged period of time, and may become permanently stuck. Humidity within the package can contribute to other undesirable effects, such as the development of discoloration, which is particularly undesirable in an optical device such as an interferometric modulator display.

A desiccant may be used to control moisture resident within the MEMS package. The nature of the desiccant usually follows one of two paths; either through a chemical reaction to capture the water such as the conversion of CaO to its hydrated form, or through adsorption of water to a high surface area lattice, such as in the SiO/AIO lattice of zeolites. The advantage of the latter is that they can be generated after saturation at relative low temperatures (<300° C.), easing the processing constraints.

### SUMMARY

The systems, methods and devices of the disclosure each have several innovative aspects, no single one of which is solely responsible for the desirable attributes disclosed herein.

One innovative aspect of the subject matter described in this disclosure can be implemented in a display device.

One implementation includes an electronic device package, comprising a substrate comprising an electronic device; a backplate sealing the electronic device within a package between the substrate and the backplate; and a desiccant covalently bonded onto at least a portion of the backplate. The desiccant can be zeolite A. The electronic device can comprise an interferometric modulator (IMOD) array or a MEMS device. In one implementation, the backplate can comprise glass. The electronic device can comprise an organic light emitting diode (OLED) device. The electronic device can comprise a cellular telephone. The substrate can comprise a glass substrate. In one implementation, the zeolite A can be covalently bonded to the backplate by reacting the zeolite particles with a difunctional adhesion promoter.

In one implementation, the desiccant can be covalently bonded to the backplate by a change in the chemical structure of the zeolite A wherein the zeolite A is chemically bonded with the backplate. The zeolite can comprise a zeolite layer that is approximately 40 microns thick. In one implementation, the electronic device can further comprise a display; a processor configured to communicate with the display, the processor being configured to process image data; and a memory device configured to communicate with the processor. The device can further comprise a driver circuit configured to send at least one signal to the display. The device can further comprise a controller configured to send at least a portion of the image data to the driver circuit. The device can further comprise an image source module configured to send the image data to the processor. The image source module can comprise at least one of a receiver, transceiver, and transmitter. The device can comprise an input device configured to receive input data and to communicate the input data to the processor.

One implementation includes a method of manufacturing an electronic device, comprising providing a substrate comprising an electronic device; providing a backplate; covalently linking a desiccant onto at least a portion of the backplate by reacting the zeolite particles with a difunctional adhesion promoter; and joining the substrate to the backplate to form an electronic device.

In another implementation, an electronic device package comprises means for supporting an electronic device; means for encapsulating the electronic device within a package between said substrate and the encapsulating means; and means for covalently bonding a desiccant onto at least a portion of the encapsulating means. In one implementation, said means for covalently bonding can be a covalent bond made by chemically reacting the encapsulating means with the desiccant. The electronic device can comprise an interferometric modulator (IMOD) array. The means for supporting can be a transparent substrate. The means for encapsulating can be a glass backplate. The electronic device can comprise a display device. In one implementation, the encapsulating means can be a backplate. The means for covalently bonding the desiccant can be a covalent bond formed by reacting the desiccant particles with a difunctional adhesion promoter. The desiccant can be covalently linked onto the encapsulating means via heating.

Yet another implementation includes a method for linking desiccant particles to a substrate, the method comprising reacting the desiccant particles with a difunctional adhesion promoter to form functionalized particles; dispersing the functionalized desiccant particles in water to form a suspension; dispensing the desiccant suspension onto the substrate; and heating the substrate so as to allow the functionalized desiccant particles to react with the substrate and become covalently bonded to the substrate.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9A is an example of a cross-section of an implementation of a MEMS device package including a desiccant supported by a shaped backplate.

FIG. 9B is an example of a cross-section of another implementation of a MEMS device package including a desiccant supported by a shaped backplate.

FIG. 10 is an example of a cross-section of an implementation of an exemplary MEMS device including the chemically bonded zeolite and substrate.

FIG. 11A is an example of a process flow illustrating steps in the assembly of a MEMS package, wherein the desiccant is baked prior to assembly.

FIGS. 11B and 11C depict one implementation of the covalent bond that is created from the cube-shaped bonding structures of the zeolite particles to the substrate.

FIG. 12A is a test slide showing moisture uptake of the zeolite particles during a baking process.

FIG. 12B is an example of a distribution of a single crystalline monolayer, as when the zeolite suspension is dispensed to a substrate, e.g., glass or silicon oxide surfaces.

FIGS. 13A and 13B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

One implementation is a MEMS device having a covalently bonded desiccant on an internal surface. The desiccant can maintain structural protection of the device and also help maintain a substantially moisture-free environment within a MEMS package to extend the lifetime of the MEMS device.

In one implementation, zeolite particles are covalently adhered to a glass or silicon oxide surface without use of a binder. This binder-free approach to desiccant thin films prevents significant outgassing, and allows almost pure zeolite to be bound with only a minute amount of adhesion/cohesion promoter. This high purity makes the system ideal for contact MEMS devices.

One example of a suitable MEMS device, to which the described implementations may apply, is a reflective display device such as an interferometric modulator (IMOD) or digital mirror device.

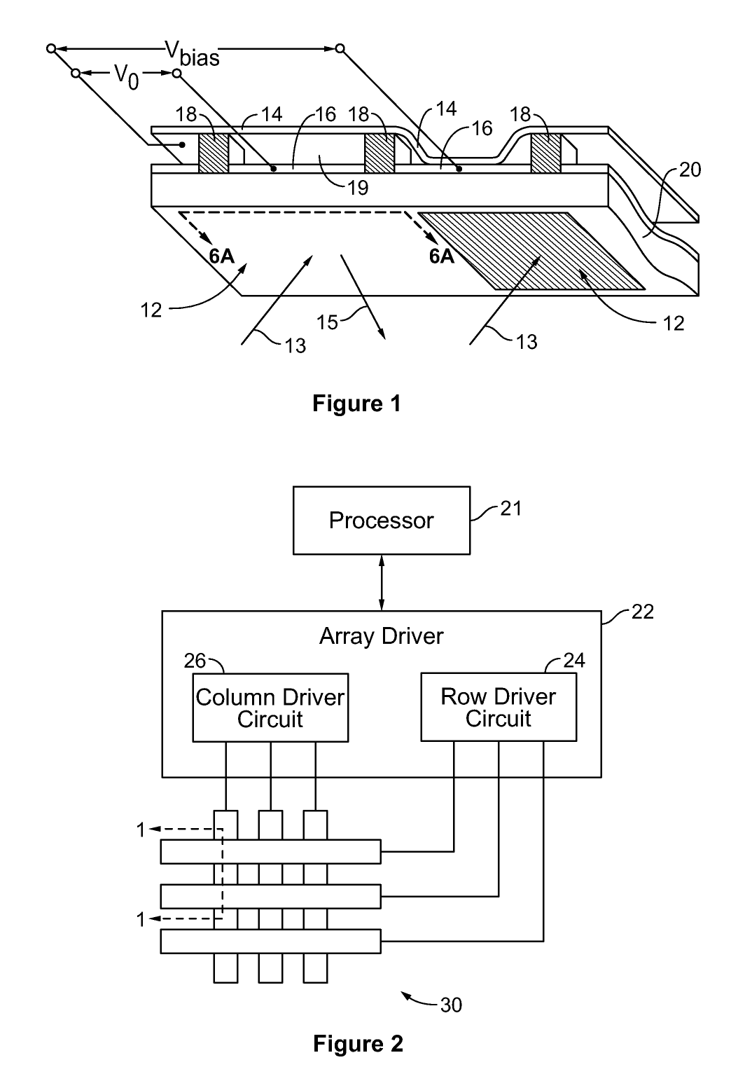

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be on the order of 1-1000 μm, while the gap 19 may be on the order of <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14a remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

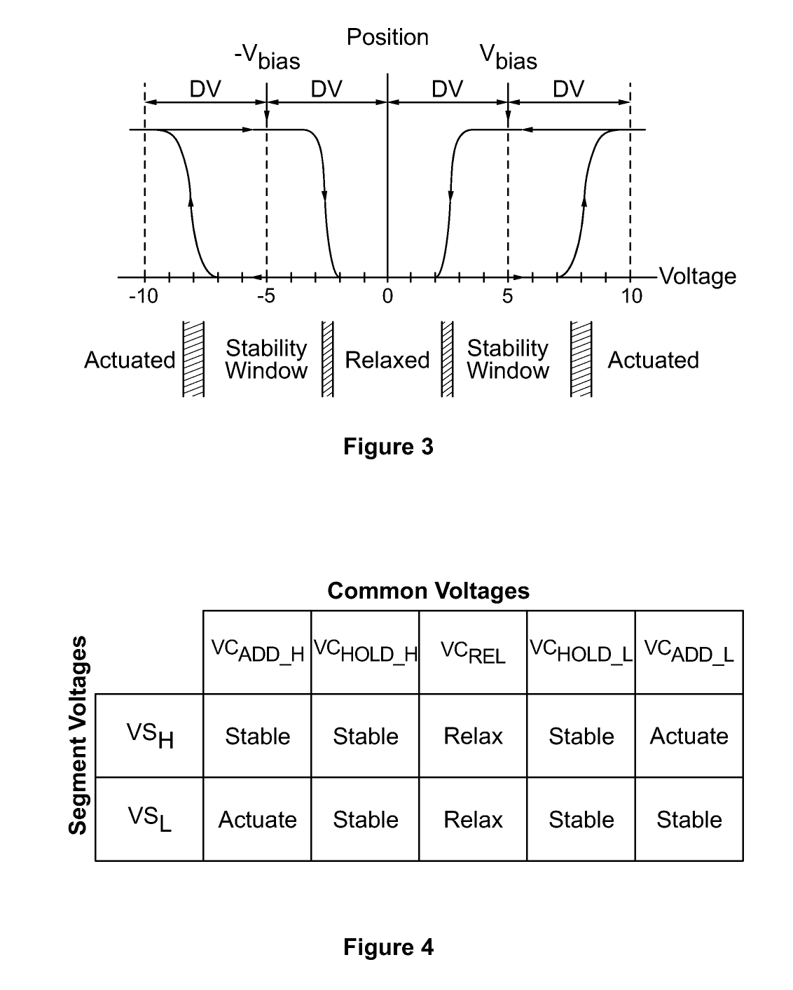

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

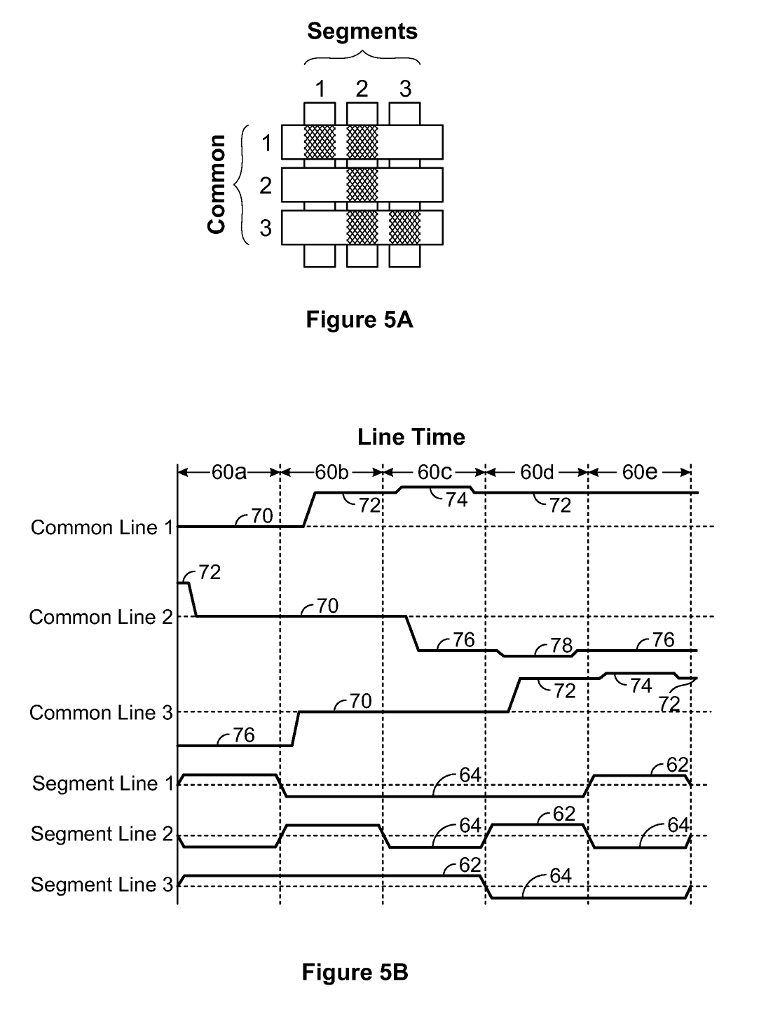

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the fours of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

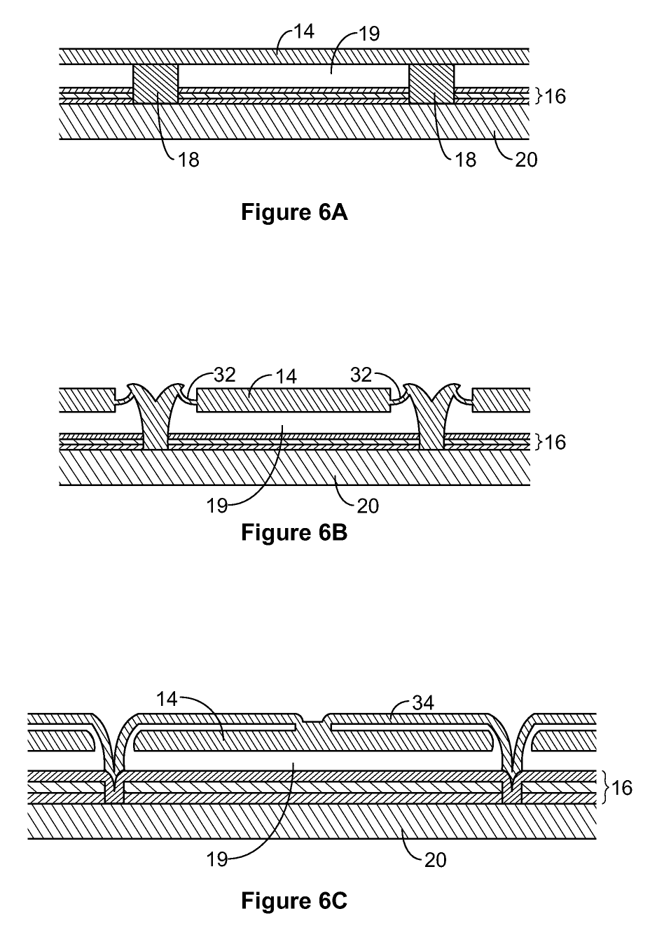

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

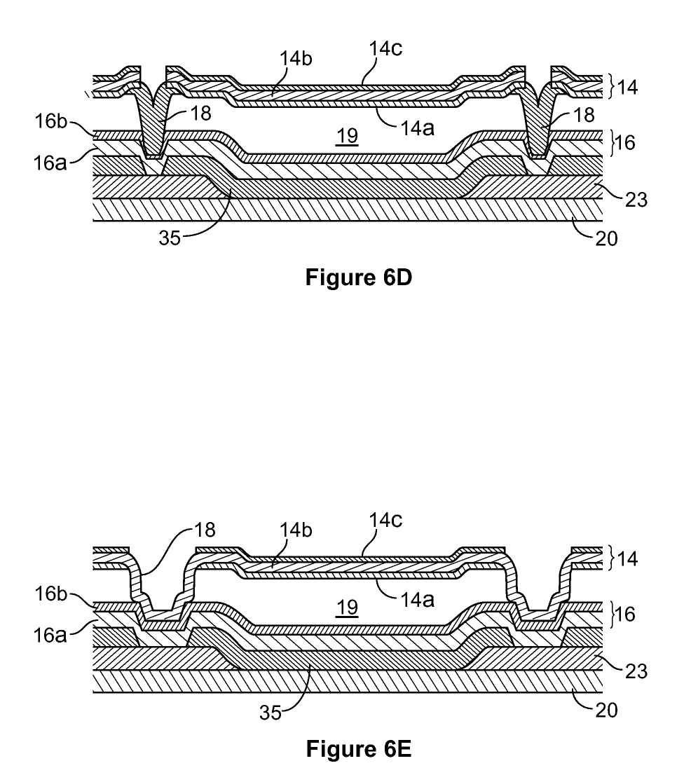

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD}_{_{—}}_{L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

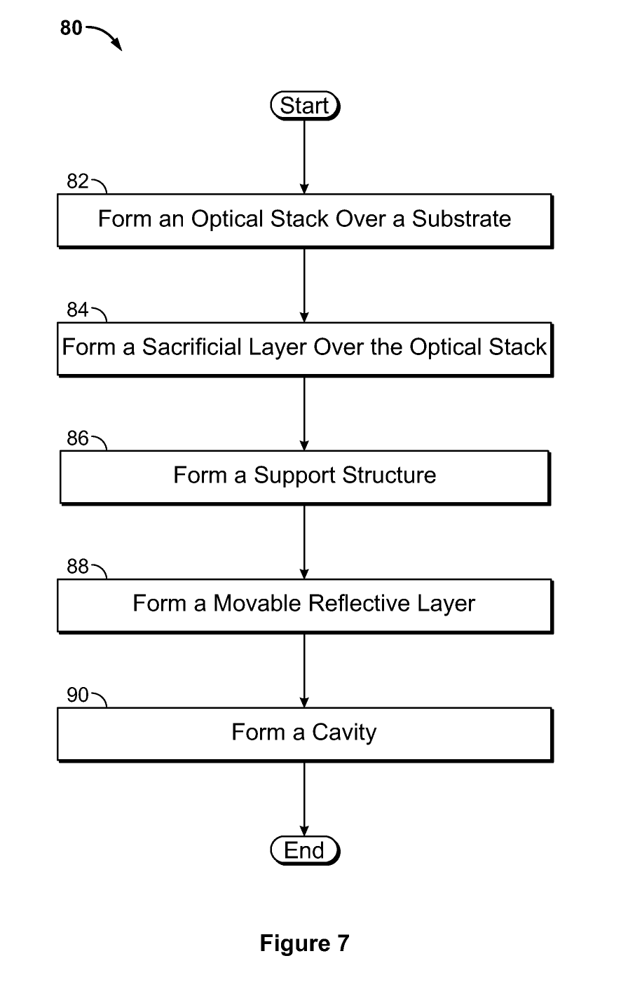

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an Al alloy with about 0.5% Cu, or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, CF₄ and/or O₂ for the MoCr and SiO₂ layers and Cl₂ and/or BCl₃ for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

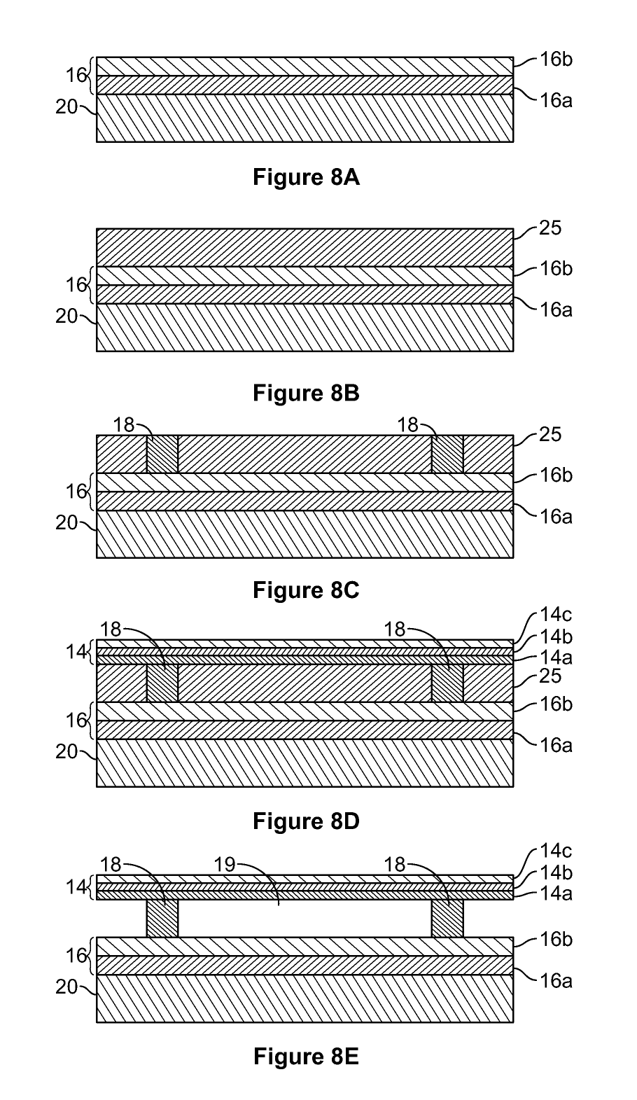

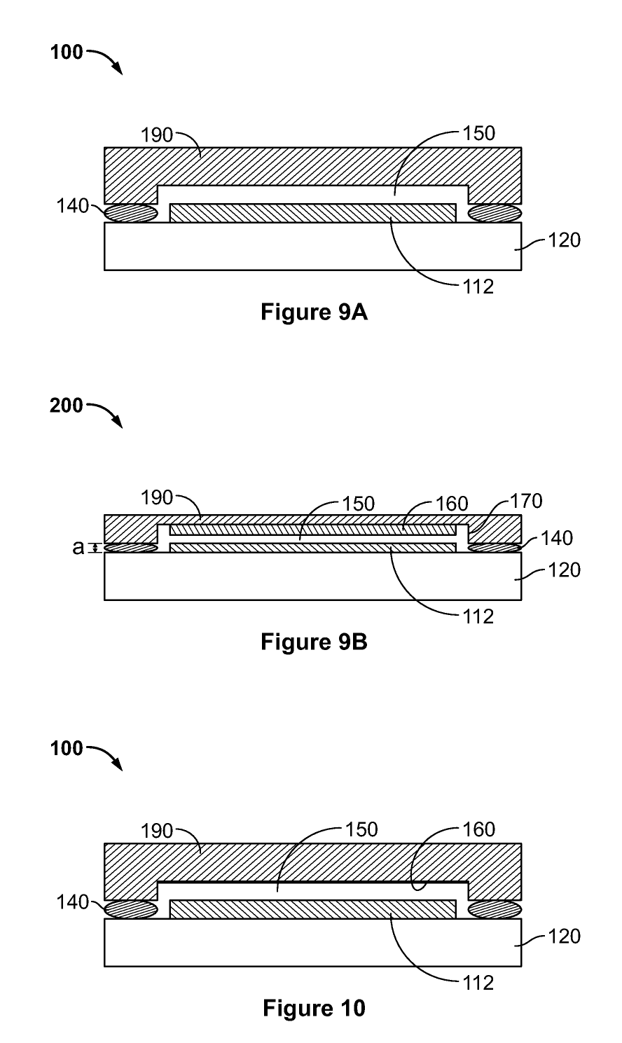

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

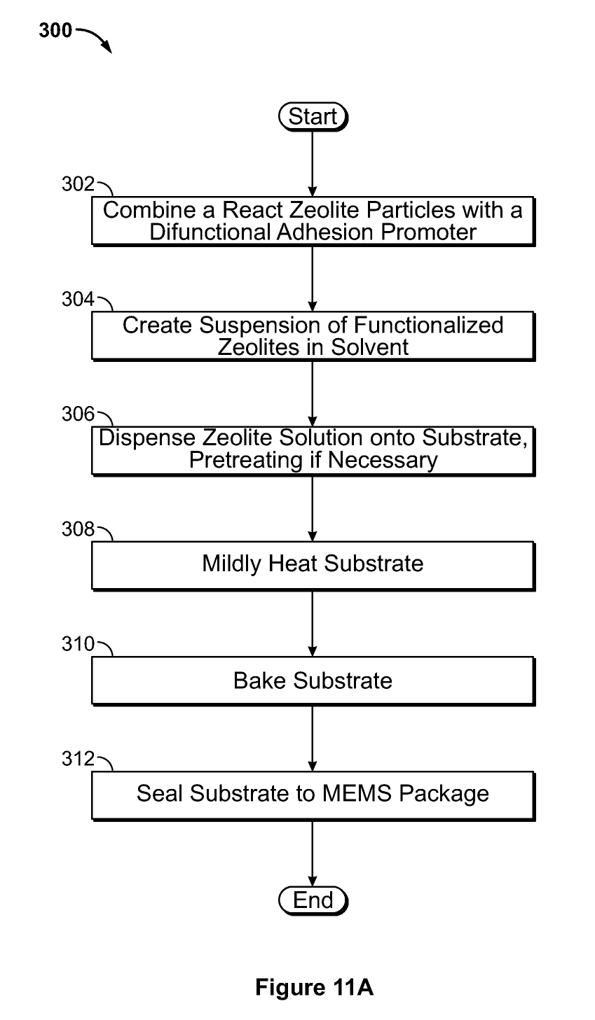

Packaging techniques for a MEMS device will be described in more detail below. A schematic of a basic package structure for a MEMS device, such as an interferometric modulator array, is illustrated in FIG. 9A. As shown in FIG. 9A, a basic package structure 100 includes a substrate 120 and a backplane cover or “cap” 190, on which an interferometric modulator array 112 is formed on the substrate 120. This backplane or cap 190 may also be referred to as a “backplate.” It will be understood that the terms “display,” “package structure,” and “package” may be used interchangeably, as used herein.

According to the implementation shown in FIG. 9A, the substrate 120 and the backplane 190 are joined by a seal 140 to form the package structure 100, such that the interferometric modulator array 112 is encapsulated by the substrate 120, backplane 190, and the seal 140. The substrate provides a means for transmitting light therethrough. The backplane provides an encapsulating means for sealing the interferometric modulator within a package between the transparent substrate and the backplane.

A wide variety of materials can be used to form the backplate 190, including glass, metal, foil, polymer, plastic, ceramic, or semiconductor materials (e.g. silicon). The substrate 120 may include, for example, glass, plastic, or transparent polymer.

The seal 140 is provided to join the substrate 120 and the backplane 190 to form the package structure 100. The seal 140 may be a non-hermetic seal, such as a conventional epoxy-based adhesive. In other implementations, the seal 140 may be a polyisobutylene (sometimes called butyl rubber, and other times PEB), o-rings, polyurethane, thin film metal weld, liquid spin-on glass, solder, polymers, or plastics, among other types of seals that may have a range of permeability of water vapor of about 0.2-4.7 g mm/m² kPa day. In still other implementations, the seal 140 may be a hermetic seal.

Generally, the packaging process to produce the display may be accomplished in a vacuum, pressure between a vacuum up to and including ambient pressure, or pressure higher than ambient pressure. The packaging process may also be accomplished in an environment of varied and controlled high or low pressure during the sealing process. There may be advantages to packaging the display in a completely dry environment, but it is not necessary. Similarly, the packaging environment may be of an inert gas at ambient conditions, or the cavity 150 may be created to contain an inert gas, such as nitrogen, at ambient conditions. Packaging at ambient conditions allows for a lower cost process and more potential for versatility in equipment choice because the device may be transported through ambient conditions without affecting the operation of the device.

As discussed above, the ability to control the moisture level in microelectronic, or MEMS packaged devices can be important to the consistent performance and lifetime of the device. For example, in MEMS contact capacitive switches, encapsulating the device in a low humidity packaged environment is necessary to avoid the capillary force-induced adhesion of the contacting surfaces.

Even slight variation of the humidity level, on the order of 10's of ppm can lead to variations in device performance caused by charging of the contact surfaces or alteration of the surface chemical environment. To control the moisture level of a package where a hermetic seal is not an option, a desiccant can be employed. The nature of the desiccant usually follows one of two paths; either through a chemical reaction to capture the water such as the conversion of CaO to its hydrated form, or through adsorption of water to a high surface area lattice, such as in the SiO/AlO lattice of zeolites. The advantage of the latter is that they can be generated after saturation at relative low temperatures (<300° C.), easing the processing constraints.

Generally, any substance that can trap moisture while not interfering with the optical properties of the interferometric modulator array may be used as the desiccant material 160. Suitable desiccant materials include, but are not limited to, zeolites, calcium sulfate, calcium oxide, silica gel, molecular sieves, surface adsorbents, bulk adsorbents, and chemical reactants. Other desiccant materials include indicating silica gel, which is silica gel with some of its granules coated with cobalt chloride. The silica changes color as it becomes saturated with water.

A desiccant, such as desiccant 160 shown in FIG. 9B, may be used to control moisture resident within the package 100. Desiccants may be used for packages that have either hermetic or non-hermetic seals. In packages having a hermetic seal, desiccants are typically used to control moisture resident within the interior of the package. In packages having a non-hermetic seal, a desiccant may be used to control moisture moving into the package from the environment. A person of ordinary skill in the art will appreciate that a desiccant may not be necessary for a hermetically sealed package, but may be desirable to control moisture resident within the package or to capture outgases materials or materials from surfaces inside the package.

FIG. 9B depicts an implementation of a package 200, which may, for example, form a part of a display device. The package 200 includes a light-transmissive substrate 120, which may preferably be a substantially transparent substrate, through which an array of interferometric modulators 112 may be viewed. The substrate 120 thus provides one means for supporting the array of interferometric modulators, or other MEMS structure. The light-transmissive substrate 120 is sealed to a backplate 190 via seal 140, providing a cavity 150 in which the interferometric modulator array 120 resides. Also within the cavity 150 is a layer of desiccant 160, which in the illustrated implementation is positioned within a recess 170 in the backplate 190. The desiccant 160 thus provides one means for absorbing moistures, the backplate 190 provides one means for supporting the desiccant, and the seal 140 provides one means for sealing the backplate 190 to the substrate 200.

Since the backplate 190 is a shaped backplate including recess 170, the height (a) of the seal 140 can be advantageously minimized while still providing sufficient clearance for the desiccant 160 to be positioned without substantial risk of mechanical interference with the interferometric modulator array 112. In certain implementations, the backplate 190 may be shaped via a sandblasting or etching process in order to form recess 170. In other implementations, the backplate 190 may be deformed to form a recess 170, or a pre-shaped backplate provided. The desiccant 160 may then be incorporated into the recess 170 within the backplate 190. In one implementation, this is done by placing the desiccant material 160 into a pouch with a membrane cover. In other implementations, the desiccant material 160 may be inserted into the cavity 150 without a pouch or membrane cover. The seal 140 is then put into place, and the backplate 190 and the light transmissive substrate 120 may be brought together to form the cavity 150 which encapsulates both the desiccant 160 and the interferometric modulator array 112.

One implementation relates to a method to dispense and react zeolite particles to a glass or silicon oxide surface such that the zeolite particles are chemically, or covalently, bonded to the substrate. In this implementation the zeolite particles are reacted with a difunctional or multifunctional adhesion promoter, followed by dispersion in solvent, and bonding, to a substrate.

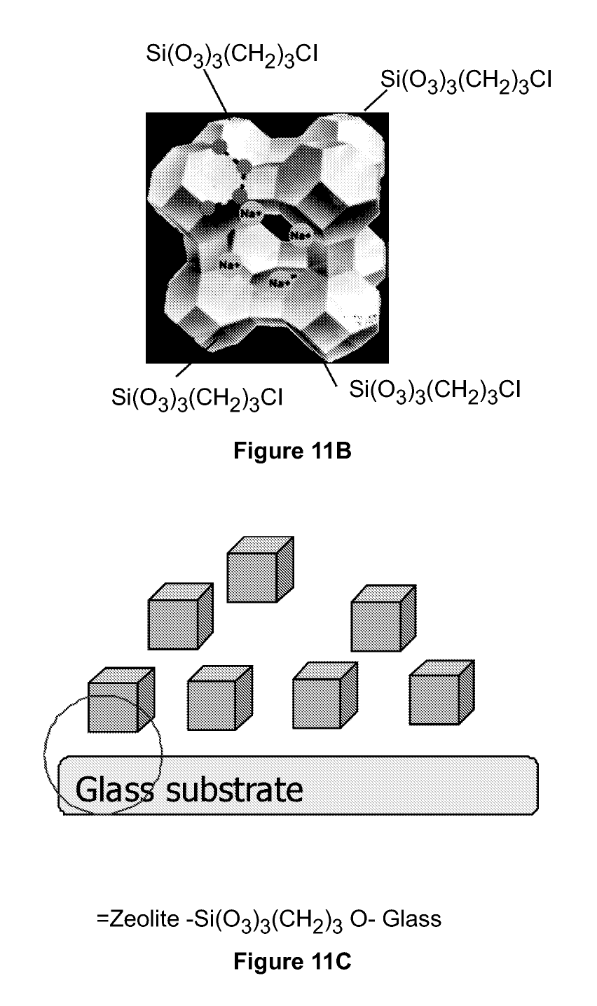

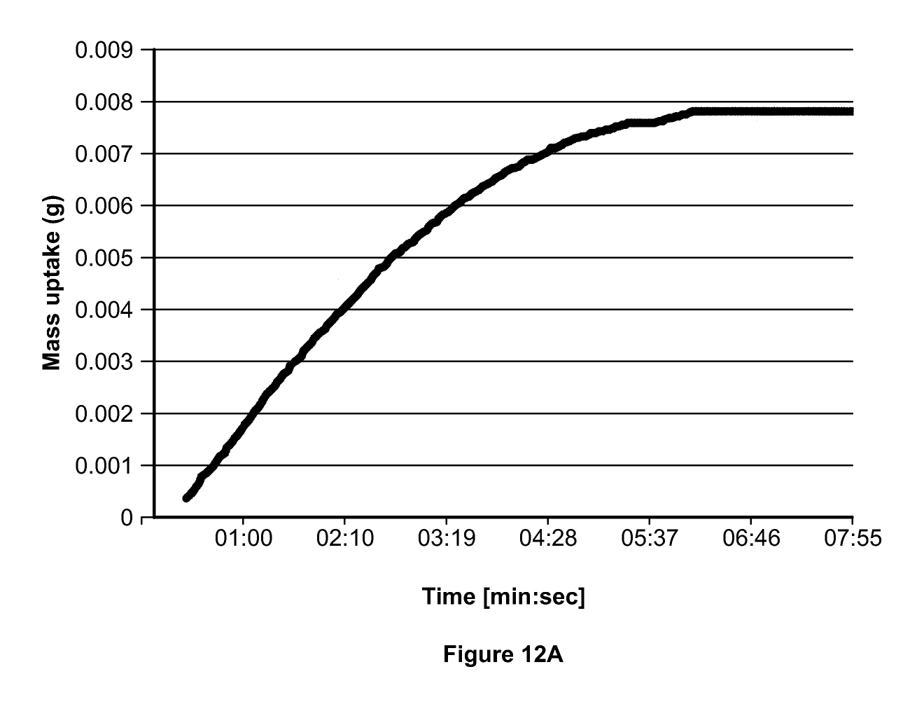

One implementation of a package 100 is shown in FIG. 10 and illustrates a structure for a MEMS device, such as an interferometric modulator array, including a substrate 120 and a backplane cover or “cap” 190, on which an interferometric modulator array 112 is foamed on the substrate 120. The substrate 120 and the backplane 190 are joined by a seal 140 to form the package structure 100, such that the interferometric modulator array 112 is encapsulated by the substrate 120, backplane 190, and the seal 140. A desiccant 160 is shown on an interior surface of the backplane 190 may be covalently linked to the surface of the backplate substrate 190. One means for linking the desiccant to the substrate is by covalent bonding, as described below at FIG. 11A. The seal 140 is then put into place, and the backplate 190 and the light transmissive substrate 120 may be brought together to faun the cavity 150 which encapsulates the interferometric modulator array 112.

FIG. 11A illustrates process flow 300 for forming the desiccant on the substrate, dispensing and covalently bonding zeolite, such as zeolite A, particles with a glass or silicon oxide surface. One example zeolite product is Zeolite 3A powder obtained from Grace Davison, chosen for its preferential adsorption of water, as opposed to zeolites with larger pore size.

In one implementation the bond group points of the zeolite are advantageously replaced with a chemical which is reactive on both ends.

Beginning at block 302 of FIG. 11A, the zeolite particles are combined and reacted with a difunctional or multifunctional adhesion promoter. Exemplary promoters include difunctional reagents, such as chloropropyltrichlorosilane, iodopropyltrimethylsiloxane, adipic acid, and chloropropyltrimethoxysilane. The reaction can proceed in dilute solution with a solvent such as hexanes or toluene (0.1-1.0 M), to allow a reaction with the surface of the zeolite particle. In one implementation, difunctional does not necessarily refer to the fact that the adhesion promoter has two functions, but rather that the compounds listed above are functionalized in two different places. For example, an adhesion promoter may have two places on the molecule that are reactive. For example, chloropropyltrichlorsilane has a chlorine atom at one end and a (trichloro) silane group at the other. When the adhesion promoters are reacted with the zeolites, one end of the adhesion promoter attaches to the zeolite and most likely loses one (or part of one) of these functional groups to form a reactive group on the zeolite. The other end of the group acts as the “glue” when it comes into contact with the glass/silicon oxide. At block 302, the (untreated) powdered zeolite is placed into an organic solvent with one of the adhesion promoters listed previously. This makes one end of the adhesion promoter react with the surface of the zeolite producing the now functionalized zeolite.

At block 304, the functionalized zeolite is removed from the solution, and added to solvent, such as water, in a ratio of between 2:3 and 10:1 solvent:zeolite by mass. The solvent is then taken away, in one implementation, by vacuum, and the remaining solid is admixed in water. The solid does not dissolve; therefore, creating a suspension of the functionalized zeolite in solvent.

At block 306, the zeolite suspension is then applied to the substrate 190, e.g., glass or silicon oxide surfaces, by dispensing or screen printing. The zeolites are distributed as a monolayer of particles, for example, a single crystalline monolayer, at high dilution. At lower solvent:particle ratios thicker layers can be formed. In one implementation, the zeolites are distributed in a hex pattern. In one implementation, the zeolites are distributed in any pattern etched onto the substrate. This distribution binds the unreacted end groups of the chosen adhesion promoter to the substrate 190. The substrate 190 may require some pretreatment, such as UV-ozone or cold plasma exposure, to prepare the surface for reaction. If a pretreatment is used, the suspension is then screen printed onto the substrate 190 after the pretreatment is applied. The pretreatment of the substrate, (e.g. glass) can depend on which compound is used in block 302 in order to make the substrate/glass react with the second functional group of the adhesive promoter.

At block 308, the substrate 190 undergoes mild heating at 40-80° C. for one hour during which the zeolite is covalently bonded to the surface of the backplate substrate 190. Mild heating times can vary from about fifteen minutes to about two hours, depending on the temperature. The zeolite suspension is heated to assist the reaction of the glass with the unreacted end of the adhesion promoter, resulting in the zeolite being covalently bound to the substrate. As previously mentioned, this is illustrated in FIGS. 11B and 11C.

At block 310, the mild heating is followed by a bake at about at least 100° C., preferably 120° C. (but not generally higher than 250° C. to prevent cracking of the substrate/glass film) to drive off residual water. The duration of the bake is determined by the amount of water remaining in the suspension. Due to its preferential adsorption of water, the zeolite may have absorbed some water during the process at block 304. As the boiling point of water is 100° C., this water would not be removed by the mild heating at block 308. At block 312, the substrate 190 is now cured and is ready to be joined, sealed or otherwise combined with the MEMS package. In this implementation, the treated substrate is the backplate substrate 190. In other implementations, the treated substrate can be any other internal surface of a substrate in the packaged MEMS assembly.

The thickness of the zeolite layer is controlled by varying the solvent:zeolite ratio, and accordingly, a thickness of 10-150 microns, and preferably, 20-100 microns can be obtained. The lower thickness limit is dictated by the zeolite particle size. Zeolites such as those previously described adsorb ˜20% of their weight in water at laboratory conditions (25° C., 60% RH). Due to the fact that the zeolite's ability to adsorb moisture is not hindered by the attachment chemistry, the water vapor adsorption capacity is directly related to the mass of zeolite adhered to the surface per unit area

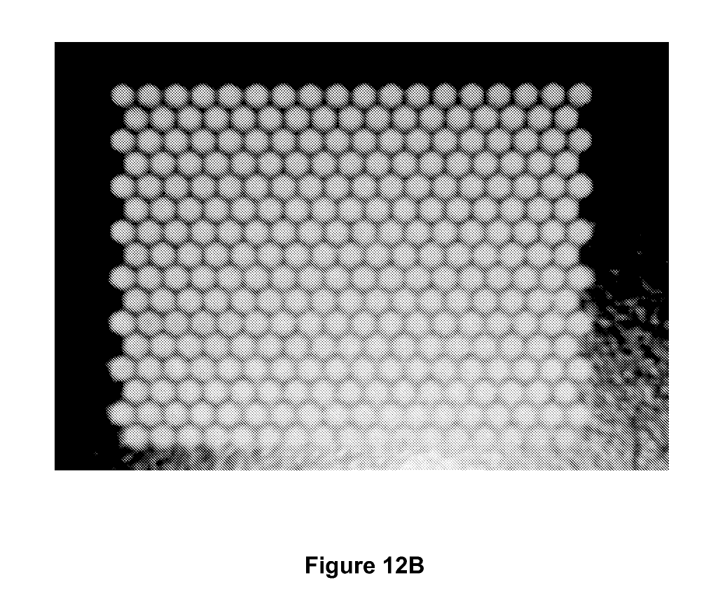

As demonstrated in FIG. 12A, using raw zeolite 3A powder yields the moisture uptake of approximately 20% by mass. The conditions for the experiment shown in FIG. 12A, 25° C. at 40% relative humidity using 1 sq inch area of zeolite 40 microns thick after activation at 150° C., resulted in a mass uptake of 7.9 mg which is nearly 20% of the mass of the deposited zeolite (40 mg). The graph of FIG. 12A illustrates this additional advantage of the system and methods described herein. In current practice, the most common methods include mixing a desiccant with a binder material which yields a low ratio of usable material transfer ration (desiccant binder). In the system and methods described herein, there is nearly 100% usable material transfer efficiency.

This binder-free approach to desiccant thin films has an added advantage of being ultra low outgassing and being pure zeolite with a minute amount of adhesion/cohesion promoter. This high purity makes the system ideal for contact MEMS.

According to the implementations described herein, the desiccant may be configured to adsorb water molecules that permeate the display package structure once it has been manufactured as well as after sealing. As can be appreciated, the desiccant maintains a low humidity environment within the package and prevents water vapor from adversely affecting the operation of the MEMS devices and any associated display electronics.

In some implementations, the desiccant can be linked to a substrate within a MEMS package. For example, the desiccant can be covalently linked to the substrate through a linker as follows:

### Desiccant-Linker-Substrate

In some implementations, the desiccant can be zeolites, calcium sulfate, calcium oxide, silica gel, molecular sieves, surface adsorbents, or bulk adsorbents. In some implementations, the substrate can be the backplate of the MEMS package.

In some implementations, the Desiccant-Linker-Substrate can be formed by reacting a desiccant with a difunctional moiety. For example, the desiccant can be zeolites and the difunctional moiety can be haloalkylsilyl halides (e.g. chloropropyltrichlorosilane), haloalkyltrialkylsiloxanes (e.g. iodopropyltrimethylsiloxane or chloropropyltrimethoxysilane), dicarboxylic acids (e.g. adipic acid), and cyclic acid anhydrides (e.g. succinic anhydride or glutaric anhydride). In the practice of some implementations, one of the functional moieties of the difunctional moiety can react with a hydroxyl group of a zeolite to afford a functionalized zeolite with one remaining functional group for further reaction with a substrate. The remaining functional group of the functionalized zeolite material can be further reacted with a hydroxyl group of the substrate to provide a Zeolite-Linker-Substrate where all attachments are through covalent linkages.

In some implementations, the Desiccant-Linker-Substrate can be formed by reacting a substrate with a difunctional moiety. For example, the substrate can be a backplate and the difunctional moiety can be haloalkylsilyl halides (e.g. chloropropyltrichlorosilane), haloalkyltrialkylsiloxanes (e.g. iodopropyltrimethylsiloxane and chloropropyltrimethoxysilane), dicarboxylic acids (e.g. adipic acid), and cyclic acid anhydrides (e.g. succinic anhydride). In the practice of some implementations, one of the functional moieties of the difunctional moiety can react with a hydroxyl group of a backplate to afford a functionalized backplate with one remaining functional group for further reaction with a desiccant. The remaining functional group of the functionalized backplate material can be further reacted with a hydroxyl group of the desiccant to provide a Zeolite-Linker-Substrate where all attachments are through covalent linkages.

In some implementations, the difunctional moiety can be chloropropyltrimethoxysilane, the desiccant can be zeolites and the substrate can be a backplate (e.g. glass). The zeolite can be treated with chloropropyltrimethoxysilane to afford Zeolite-O—Si(OCH₃)₂(CH₂CH₂CH₂)—Cl mono-functional intermediate. The zeolite-O—Si(OCH₃)₂(CH₂CH₂CH₂)—Cl can be coated onto the backplate under appropriate conditions to afford Zeolite-O—Si(OCH₃)₂(CH₂CH₂CH₂)—O-backplate. The linkage from the zeolite to the linker can be through a covalent silicon-oxygen bond and the linkage from the linker to the backplate can be through a covalent carbon-oxygen bond.

In some implementations, the difunctional moiety can be succinic anhydride, the desiccant can be zeolites and the substrate can be a backplate (e.g. glass). The zeolite can be treated with glutaric anhydride to afford Zeolite-O—C(═O)(CH₂CH₂CH₂)C(═O)OH mono-functional intermediate. The zeolite-O—C(═O)(CH₂CH₂CH₂)C(═O)OH can coated onto the backplate and treated under appropriate conditions to afford zeolite-O—C(═O)(CH₂CH₂CH₂)C(═O)-backplate. The linkage from the zeolite to the linker can be through a covalent carbon-oxygen bond and the linkage from the linker to the backplate can be through a covalent carbon-oxygen bond.

Typically, in packages containing desiccants, the lifetime expectation of the device may depend on the lifetime of the desiccant. When the desiccant is fully consumed, the interferometric modulator array 120 may fail to operate as sufficient moisture enters the cavity 150 and causes damage to the array 120. The theoretical maximum lifetime of the display device is determined by the water vapor flux into the cavity 150 as well as the amount and type of desiccant material.

The theoretical lifetime of the device may be calculated with the following equations:

$$lifetime = ( \frac{desiccant\_capacity ( g )}{water\_vapor \_flux ( g \text{/} area \text{/} day ) * perimeter\_seal \_area} ) * 4$$

$$water vapor flux = - P \frac{d p}{d t}$$

where P is the water vapor permeation coefficient for the perimeter seal 280 and dp/dt is the water vapor pressure gradient across the width of the seal 280.

The definition of the desiccant capacity is fairly straightforward for materials such as calcium oxide, where the moisture is bound via a chemical reaction resulting in the formation of calcium hydroxide, and no reverse reaction is present at normal device operation or storage conditions. In the case of zeolites, where adsorption is the primary mechanism of moisture capture, an equilibrium is established between the zeolite-water complex and the environment. Zeolite capacity can be often stated under laboratory conditions (25° C., 60% RH) instead of the low moisture levels found in a packaged device. In a packaged device zeolites can mediate the moisture level through equilibrium adsorption. Still, the moisture level in the packaged device can increase as a function of the total number of water molecules in the package. The desiccant capacity, then, is determined by the acceptable moisture level threshold in a package as defined by impact of moisture on device performance and lifetime. For example, to maintain a 40 ppm water environment only 20% of the zeolite's capacity at 25° C., 60% RH may be used.

In the implementation of a display having a hermetic seal, the lifetime of the device is not as dependent on the desiccant capacity, or the geometry of the seal. In display devices in which the seal 140 is not hermetic, the lifetime of the device is more dependent on the capacity of the desiccant to absorb and retain moisture.

In addition to providing a controlled package environment within the package with respect to humidity, the desiccant and/or the MEMS structure may be selected to avoid or minimize the harmful effect of other material within the package environment. Such harmful material within the package environment may in certain implementations be eliminated or minimized. In other implementations, the MEMS structure itself may be designed so as to minimize the effects of said potentially harmful material on the MEMS structure, potentially facilitating the use of a wider range of desiccant materials.

### Example 1

### Synthesis of Modified Backplate

Zeolite 3A powder is combined with chloropropyltrimethoxysilane in an organic solvent, such as hexanes or toluene (0.1-1.0 M). After completion of the reaction the organic solvent is removed and the remaining solid functionalized zeolite is then added to water in a ratio of between 2:3 and 10:1 water:zeolite by mass to provide a suspension of the zeolite in water. The zeolite suspension is then applied to a substrate, e.g., glass or silicon oxide surfaces, by dispensing or screen printing. The zeolites are distributed as a monolayer of particles, for example, a single crystalline monolayer as shown in FIG. 12B. The substrate undergoes mild heating at 40-60° C. for one hour during which the zeolite is adhered to the surface of the substrate via the adhesion moiety. Mild heating times can vary from fifteen minutes to two hours, depending on the temperature. The zeolite suspension is heated to assist the reaction of the glass with the unreacted end of the adhesion promoter, resulting in the zeolite being bound to the substrate. The mild heating is followed by a bake at about at least 100° C., preferably 120° C. (but not higher than 300° C. to prevent cracking of the substrate/glass film) to drive off residual water. The time for the bake is determined by the amount of water remaining in the suspension. Excess water is removed by heating the treated substrate to a temperature of at least 100° C., preferably 120° C., but not higher than 250° C. to prevent cracking of the zeolite film. The functionalized backplate is then joined, sealed or otherwise combined with the MEMS package.

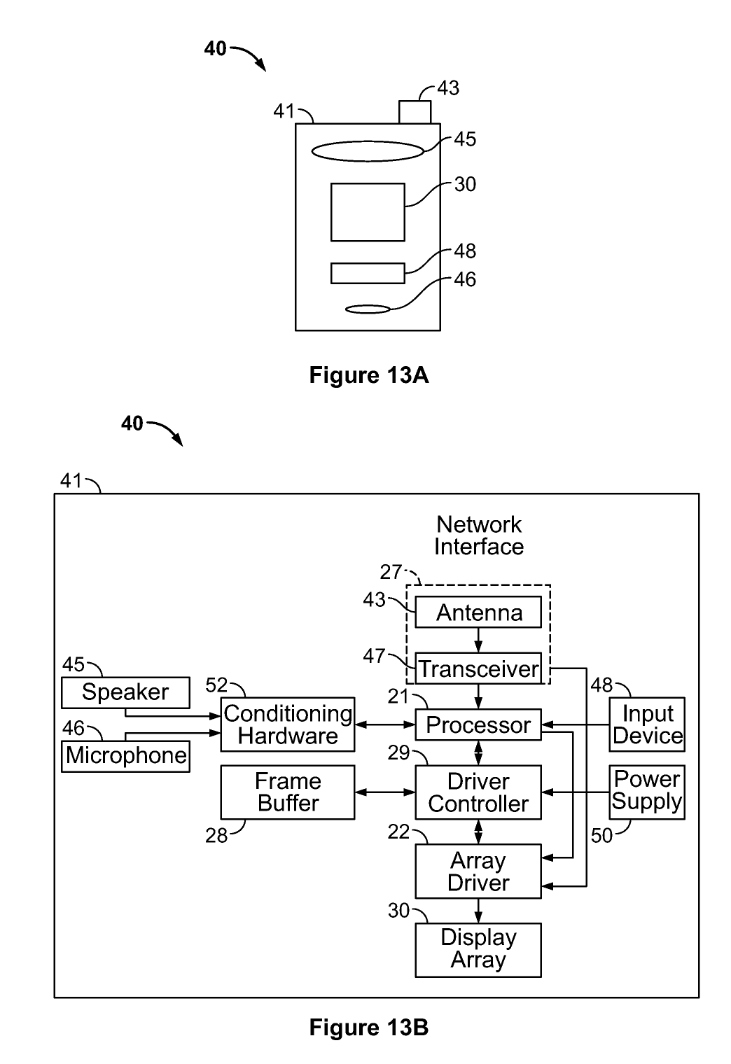

FIGS. 13A and 13B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 13B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

1. A device package, comprising:
a substrate supporting an electronic device;
a backplate sealing the electronic device between the substrate and the backplate; and
a desiccant covalently bonded onto at least a portion of the backplate.

2. The device package of claim h wherein the desiccant is zeolite A.

3. The device package of claim 2, wherein the desiccant is distributed onto at least a portion of the backplate as a monolayer of zeolite A particles.

4. The device package of claim 2, wherein the zeolite A includes a zeolite layer that is approximately 40 microns thick.

5. The device package of claim 2, wherein the zeolite A is covalently bonded to the backplate by reacting zeolite A particles with a difunctional adhesion promoter.

6. The device package of claim 5, wherein the difunctional adhesion promoter is selected from the group consisting of chloropropyltrichlorosilane, iodopropyltrimethylsiloxane, adipic acid, and chloropropyltrimethoxysilane.

7. The device package of claim 5, wherein the desiccant is covalently bonded to the backplate by a change in the chemical structure of the zeolite A
wherein the zeolite A is chemically bonded with the backplate.

8. The device package of claim 2, wherein the zeolite A is covalently bonded to the backplate by reacting the zeolite A particles with a difunctional moiety.

9. The device package of claim 8, wherein the difunctional moiety is selected from the group consisting of a haloalkylsilyl halide, a haloalkyltrialkylsiloxane, a dicarboxylic acid, and a cyclic acid anhydride.

10. The device package of claim 1, wherein the substrate includes glass.

11. The device package of claim 1 claim 2, wherein the backplate includes glass.

12. The device package of claim 1, wherein the electronic device is selected from the group consisting of an interferometric modulator (IMOD) array, a microelectromechanical systems (MEMS) device, an organic light emitting diode (OLED) device, and a cellular telephone component.

13. The device package of claim 1 further comprising:
a processor configured to communicate with the electronic device, the processor being configured to process image data; and
a memory device configured to communicate with the processor.

14. The device package of claim 13, further comprising:
a driver circuit configured to send at least one signal to the electronic device.

15. The device package of claim 14, further comprising:
a controller configured to send at least a portion of the image data to the driver circuit.

16. The device package of claim 13, further comprising:
an image source module configured to send the image data to the processor, wherein the image source module includes at least one of a receiver, transceiver, and transmitter.

17. The device package of claim 13, further comprising:
an input device configured to receive input data and to communicate the input data to the processor.

18. A method of manufacturing an electronic device, comprising:
providing a desiccant substrate; and
covalently linking a desiccant onto at least a portion of the desiccant substrate by reacting the desiccant particles with a difunctional adhesion promoter or a difunctional moiety.

19. A device package, comprising:
a substrate supporting an electronic device;
a backplate;
a desiccant; and
means for promoting formation of a covalent bond between the desiccant and at least a portion of the backplate.

20. The device package of claim 19, wherein the promoting means is a linker configured to chemically react with the desiccant to form functionalized desiccant particles.

21. The device package of claim 20, wherein the linker is a difunctional adhesion promoter selected from the group consisting of chloropropyltrichlorosilane, iodopropyltrimethylsiloxane, adipic acid, and chloropropyltrimethoxysilane.

22. The device package of claim 20, wherein the linker is a difunctional moiety selected from the group consisting of a haloalkylsilyl halide, a haloalkyltrialkylsiloxane, a dicarboxylic acid, and a cyclic acid anhydride.

23. The device package of claim 19, wherein the desiccant is zeolite A.

24. The device package of claim 19, wherein the electronic device includes an interferometric modulator (IMOD) array.

25. The device package of claim 19, wherein the electronic device includes a display device.

26. The device package of claim 19, wherein the backplate includes glass.

27. The device package of claim 19, wherein the desiccant is covalently linked onto the backplate via heating.

28. (canceled)

29. The method of claim 18, wherein covalently linking the desiccant onto at least a portion of the desiccant substrate includes:
dispensing a desiccant suspension onto at least a portion of the desiccant substrate; and
heating the desiccant substrate so as to allow the desiccant particles to react with the desiccant substrate and become covalently bonded to the desiccant substrate.

30. The method of claim 29, further comprising forming the desiccant suspension, wherein forming the desiccant suspension includes:
reacting the desiccant particles with a difunctional adhesion promoter or a difunctional moiety to form functionalized particles; and
dispersing the functionalized desiccant particles in water to form a suspension.

31. The method of claim 18, further comprising:
providing a device substrate including an electronic device; and
joining the device substrate to the desiccant substrate to form a packaged electronic device.
